(19) United States
(12) Patent Application Publication
(10) Pub. No.: US 2022/0019705 A1
(43) Pub. Date: Jan. 20, 2022

(54) CHARACTERIZATION OF THE DEFORMATION PROPERTIES OF A BALL GAME RACKET STRING PATTERN

(71) Applicant: Head Technology GmbH, Kennelbach (AT)

(72) Inventors: Stefan MOHR, Dornbirn (AT); Daniel LAU, Dornbirn (AT); Nathan ELLIOTT, Wolfurt (AT)

(73) Assignee: Head Technology GmbH, Kennelbach (AT)

(21) Appl. No.: 17/377,745

(22) Filed: Jul. 16, 2021

(30) Foreign Application Priority Data
Jul. 17, 2020 (DE) 10 2020 004 304.6

(51) Int. Cl. G06F 30/10

(52) U.S. Cl. CPC G06F 30/10; A63B 49/02

(57) ABSTRACT

The present invention relates to a method for characterizing the deformation properties of a string pattern of a ball game racket frame as well as to the representation of a string pattern image of a strung ball game racket frame.

This patent application claims the benefit under 35 U.S.C. 119 to German Utility Model Application No. DE 10 2020 004 304.6, filed on Jul. 17, 2020, the entirety of which is incorporated herein by reference.

The present invention relates to a method for characterizing the deformation properties of a string pattern of a ball game racket frame as well as to the representation of a string pattern image of a strung ball game racket frame.

It has long been known that the string pattern of a ball game racket has a decisive influence on the playability of the ball game racket, which is of course due to the fact that the ball is not hit with the racket frame, but that the strings establish the contact between the ball and the frame. Therefore, elaborate measurements with ball game rackets have been made time and again to investigate the influence of different string patterns on the physical properties of the ball game racket (cf., for example, Y. Kanemitsu, “The relationship between racket properties and player preference” and U.S. Pat. No. 3,999,756). Of course, such experiments also play an important role in today's racket development. However, it would be desirable to describe different ball game racket string patterns as precisely as possible using the simplest possible means.

It is therefore an object of the present invention to provide a method for characterizing a ball game racket string pattern that enables reliable results for comparing different string patterns without performing complex experiments.

This object is achieved with a method according to claim 1. Preferred embodiments of the method according to the invention are described in the dependent claims.

Accordingly, the present invention is directed to a method for characterizing the deformation properties of a string pattern of a ball game racket frame which is strung in a string bed plane and comprises a racket head with an inner contour facing the string pattern, wherein the string pattern comprises intersecting main strings and cross strings forming a plurality of points of intersection. Firstly, the string pattern is modeled using the geometry of the intersecting strings and the inner contour of the racket head. Then, a defined preload is applied to the string pattern thus modeled. Subsequently, at least one physical quantity describing the local deformation of the string pattern is determined at at least three points of the string pattern in response to a defined force acting on the respective point of the string pattern. At least one local property of the string pattern at the at least three points of the string pattern is derived from the at least one physical quantity thus determined and the defined force. The at least three points of the string pattern are then classified using the physical quantity or quantities respectively determined there and/or using the property or properties derived for said points, and the string pattern is represented by specifying the class of the at least three points of the string pattern.

In other words, the invention is based, i.a., on the finding that decisive statements concerning the characterization of a string pattern can also be derived from a modeled string pattern, which makes it possible to compare a large number of different ball game rackets with respect to their string pattern with a manageable amount of effort. In particular, the aforementioned local properties can be determined at a plurality of points on the string pattern, for example at each individual point of intersection of the main strings and cross strings, without much additional effort, whereas such a precise measurement would hardly be practicable in the context of an experiment. A further advantage of the method according to the invention consists in that not only actually existing string patterns of existing ball game rackets can be compared with each other, but also, for example, a wide variety of test string patterns can be theoretically analyzed with regard to their characterization in the context of a development process.

Modeling the string pattern, applying a defined preload and determining the local deformation in response to a defined force can be carried out, for example, using finite element calculation software. With the aid of such a finite element method, relevant material properties such as, for example, Young's modulus, density and coefficient of thermal expansion can also be assigned to the individual strings.

The derivation of at least one local property of the string pattern from the at least one physical quantity and the defined force can be carried out purely mathematically on the basis of known physical relationships or also in the course of a simulation.

In the simplest case of the claimed method, a defined normal force (perpendicular to the string bed plane) is applied at each of the at least three points of the string pattern and the punctual (punctiform) deflection of the string pattern at the respective points perpendicular to the string bed plane is determined. For example, the local stiffness of the string pattern at the respective points in a direction perpendicular to the string bed plane can then be derived therefrom (as a ratio of force to deformation). Accordingly, the string pattern can be represented by specifying the local stiffness of each of the at least three points of the string pattern in order to characterize it quantitatively.

Analogously, a wide range of physical quantities describing the local deformation of the string pattern can actually be determined and different local properties of the string pattern can be derived therefrom.

For example, the at least one physical quantity describing the local deformation of the string pattern may comprise one or a combination of the following quantities: the vector describing the punctual three-dimensional deformation at the respective points, one or more components of said vector, the length of said vector; the punctual deflection of the string pattern at the respective points perpendicular to the string bed plane; the punctual deflection of the string pattern at the respective points parallel to the string bed plane; the vectors describing the local deformations in a defined area around the respective points, one or more components of said vectors, the length of said vectors; the local deflections of the string pattern in a defined area around the respective points perpendicular to the string bed plane; the local deflections of the string pattern in a defined area around the respective points parallel to the string bed plane.

The force acting on at least three points of the string pattern can be a normal force acting perpendicular to the string bed plane, or an arbitrarily oriented force, which comprises a component parallel to the string bed plane. It is preferred to carry out the method for all points of the string pattern with the same defined force in order to ensure a corresponding comparability of the determined physical quantities and the properties derived therefrom. However, the method can also be carried out several times for different forces in order to be able to derive different local properties one after the other.

The derived local properties of the string pattern may be one or a combination of the following properties: local stiffness, local compliance, local contact time, local stiffness in a direction perpendicular to the string bed plane, local stiffness in a direction parallel to the string bed plane, local compliance in a direction perpendicular to the string bed plane, local compliance in a direction parallel to the string bed plane, angle of deflection with respect to the string bed plane normal, local spin potential, local control properties, membrane deformation properties.

Preferably, the classification is graphically visualized in the representation, for example by assigning one or more of the following graphical parameters to predetermined classes of the classification: color value, tonal value, hatching. However, other representations are also conceivable. For example, the at least three points of the string pattern may be provided with numerical values corresponding to the respective classification. As already mentioned, according to the invention, for example, several points of intersection of the string pattern or meshes of the string pattern adjacent thereto may be colored with different colors according to the local stiffness. Of course, two or more representations of the string pattern image, each indicating a different class, can also be created based on different properties of the string pattern. Alternatively, different classifications can be combined in one representation. For example, a classification on the basis of the local stiffness may be represented by means of a color value and, in the same representation, a classification on the basis of the local spin potential may be represented by means of an additional hatching.

Preferably, the string pattern is modeled using the geometry of the intersecting strings and the inner contour of the racket head under one or more of the following basic conditions: definition of the inner contour of the racket head as infinitely stiff, specification of a progression of the stiffness of the racket head within and/or perpendicular to the string bed plane along the inner contour of the racket head, modeling of the string pattern as a fixed net. Any data can be used to model the string pattern, for example CAD data of the geometry of the intersecting strings and/or the inner contour of the racket head, wherein the data of the geometry of the intersecting strings comprise the positions of the points of intersection of the strings.

Generally, the method according to the invention can be carried out at any points of the modeled string pattern, i.e. at all points of a main and/or cross string of the string pattern. However, it is preferred to perform the method according to the invention at specific points of the string pattern, for example at specific symmetry points. Accordingly, the at least three points of the string pattern preferably comprise at least three points of intersection of the string pattern. Alternatively or additionally, the at least three points of the string pattern preferably comprise at least three points on a central axis between two adjacent points of intersection. However, under certain conditions, it may also be of interest to perform the method at a plurality of points along a main string or along a cross string between two adjacent points of intersection in order to get an idea of the variability of the derived local properties along the string progression.

Preferably, the at least three points of the string pattern comprise at least four, five, six, seven, eight, nine, more preferably at least ten, at least 15, at least 20, and particularly preferably at least 25, at least 30, at least 35 points of the string pattern. Once the string pattern has been modeled, the additional effort for determining the physical quantity describing the local deformation of the string pattern and for deriving the corresponding local properties of the string pattern is very manageable so that according to the invention it is appropriate to analyze and characterize the string pattern at as many points as possible over as large an area as possible. In particular, the course of the derived local properties over the entire string bed plane may also be important for the evaluation of the string pattern.

The present invention is further directed to a representation of a string pattern image of a strung ball game racket frame, comprising a representation of the string pattern, optionally including a representation of at least a portion of the ball game racket frame, as well as a classification of at least three points of the string pattern on the basis of the derived local property or properties of the string pattern at said points. The classification may be graphically visualized in the representation, preferably by assigning one or more of the following graphical parameters to predetermined classes of the classification: color value, tonal value, hatching.

Furthermore, the present invention is directed to a set comprising a ball game racket frame and a representation of the string pattern image determined from the ball game racket frame. If a ball game racket frame is offered to the customer in the form of such a set, the customer can compare the associated string pattern image with regard to its deformation properties with the string pattern image of his/her own previously used ball game racket and/or with string pattern images of other ball game rackets offered before making his/her purchase decision and accordingly can also base his/her purchase decision quite specifically on the specific string pattern.

In the following, the present invention is explained in more detail by means of a particularly preferred embodiment of the method according to the invention with reference to the Figures, in which:

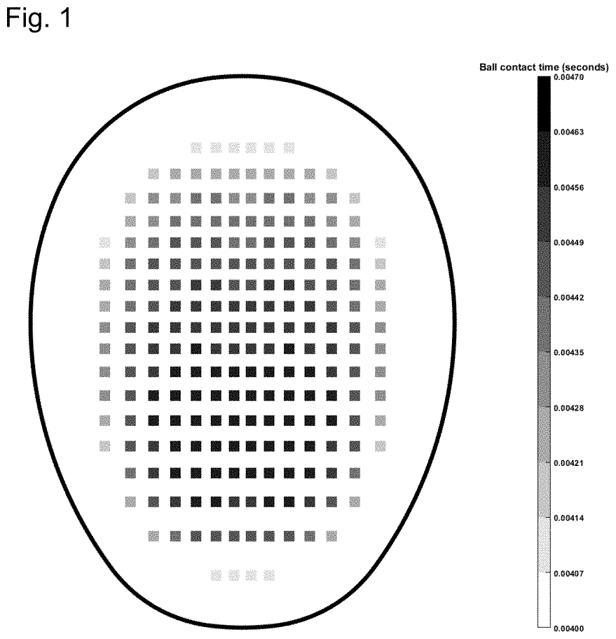

FIG. 1 shows the ball contact time determined according to the invention for a first exemplary string pattern;

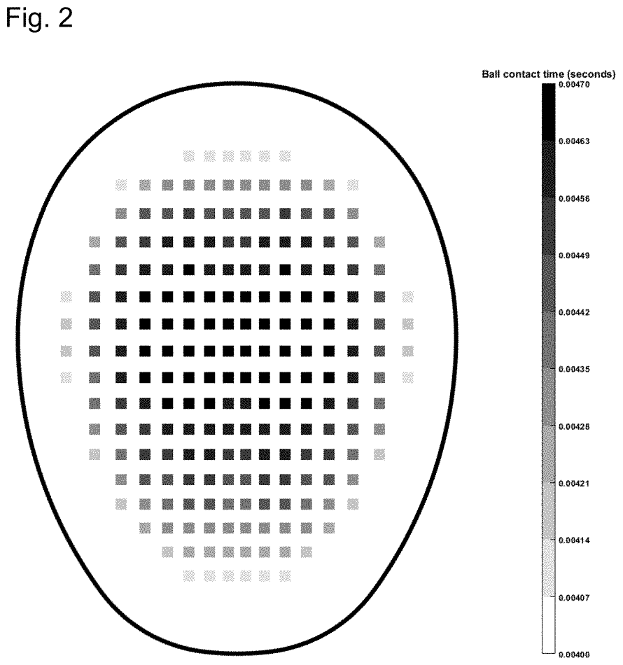

FIG. 2 shows the ball contact time determined according to the invention for a second exemplary string pattern; and

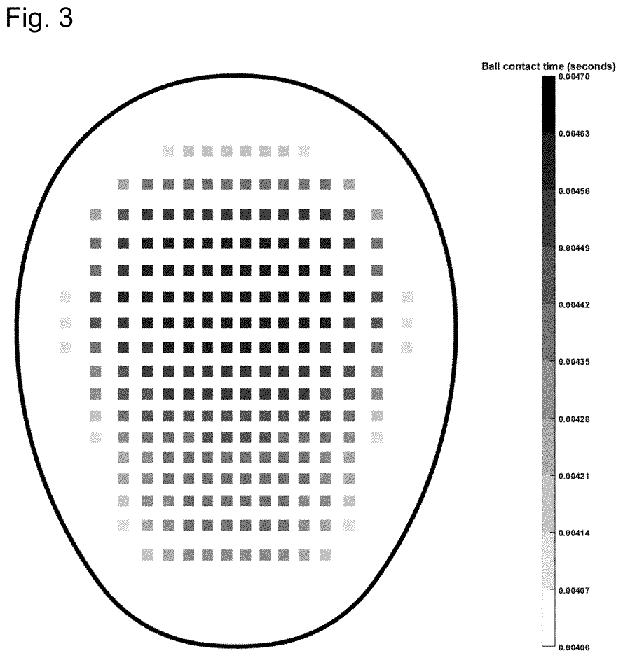

FIG. 3 shows the ball contact time determined according to the invention for a third exemplary string pattern.

FIGS. 1 to 3 respectively show the ball contact time determined according to the invention for three different string patterns of a tennis racket. The starting point for the method according to the invention of this preferred embodiment was in each case a CAD line file in IGS format of all cross and main strings of a string pattern as well as the inner contour of the racket head of the respective tennis racket. The points of intersection of all main and cross strings were already connected in said file. Said file was read into a commercial FE software for implicit static analysis and a finite element net of beam elements having a corresponding string diameter was generated. Then, material properties such as Young's modulus (Young's modulus of the strings here: 10 GPa), density (density of the strings here: 1.3 g/cm³) and a fictitious coefficient of thermal expansion were assigned to the strings having a diameter of 1.25 mm in the present case as well as to the inner contour of the racket head in order to achieve the preload. In the present embodiment, the racket head was defined as infinitely stiff. However, it would also be possible to assign a specific stiffness to the racket head that varies along the length both in the direction of the string bed plane and transverse to the string bed plane.

The nodes of the string pattern were then locked and all beam elements of the finite element net were cooled to achieve a preload of 180 N per main and cross strings. Subsequently, all nodes were released again and the edge nodes, i.e. the connections of the main and cross strings with the inner contour of the racket head, were locked.

In the present embodiment, identical main and cross strings were used and an identical pre-load was applied thereto. However, the method according to the invention can also be carried out with so-called hybrid string patterns, in which the main and cross strings differ from one another in their material properties, their diameter and/or the preload applied thereto.

In the present embodiment, the string pattern image was modeled as a fixed net. This means that the main and cross strings are not interwoven with each other in such a modeling, but are modeled as fixed connection points.

Once the string pattern had been modeled in this way and a defined preload applied thereto, at least one physical quantity describing the local deformation of the string pattern could be determined at at least three points of the string pattern in response to a defined force acting on the respective point of the string pattern. In the present embodiment, this was done in the context of a calculation loop for all points of intersection of the main and cross strings. For each point of intersection, a normal force of 100 N was applied to that point of intersection and the vector describing the punctual three-dimensional deformation at the respective point of intersection was calculated. Subsequently, the force was canceled again and the same force was applied to the next point of intersection.

Upon completion of said calculation loop, a deformation vector Def (xi, yj) is available for each point of intersection (xi, yj) of the main string i with the cross string j. Along with the applied force F=100 N, the local stiffnesses of the string pattern can be determined therefrom:

$${k}_{i j} = \frac{F}{\vert Def ( {x}_{i} , {y}_{j} ) \vert}$$

Of course, the local compliance of the string pattern can also be determined as an inverse ratio instead:

$${s}_{i j} = \frac{\vert Def ( {x}_{i} , {y}_{j} ) \vert}{F} = 1 / {k}_{i j}$$

Furthermore, the local contact times can also be calculated from the local stiffnesses kij according to:

$${T}_{i j} = π \sqrt{\frac{m}{{k}_{ij}}}$$

wherein m denotes the mass of the ball.

As already initially explained, individual components of the local stiffness can also be determined if not (as in this embodiment) a pure normal force acts on the string pattern points, but a general force vector F=(Fx, Fy, Fz). In this case, for example, the local stiffness in the direction perpendicular to the string bed plane can be determined according to:

$${k}_{z} = \frac{{F}_{z}}{{Def}_{z}}$$

Also the angle of deflection with respect to the string bed plane normal can be determined according to:

$$α = a tan \frac{{Def}_{X}}{{Def}_{Z}}$$

FIGS. 1 to 3 respectively show the results of the analysis described above for the example of the ball contact time Tᵢⱼ for three different string patterns of a tennis racket. In this representation, a square is shown for each mesh of the string pattern, the gray tone of which corresponds to the ball contact time in seconds, wherein the scale ranges from 0.0040 s (white) to 0.0047 s (black).

As can be clearly deduced from FIGS. 1 to 3 (a correspondingly colored representation is actually to be preferred in this respect), the areas of the string pattern which exhibit the longest contact time, i.e. the areas which allow the greatest control, are shifted further and further upwards from a grip-side position towards the end of the racket head. This can be excellently visualized by means of a representation according to the invention and, thus, the playing properties of the string pattern can be characterized accordingly well.

The other aforementioned local properties of the string pattern and the classifications based thereon can, of course, be analogously represented. Different properties can be represented in different graphics or combined in one and the same graphic.

1. A method for characterizing a string pattern of a ball game racket frame which is strung in a string bed plane and comprises a racket head with an inner contour facing the string pattern, wherein the string pattern comprises intersecting main strings and cross strings forming a plurality of points of intersection, said method comprising the steps of:
(a) modeling the string pattern using the geometry of the intersecting strings and the inner contour of the racket head;
(b) applying a defined preload to the modeled string pattern;
(c) determining at least one physical quantity describing the local deformation of the string pattern at at least three points of the string pattern in response to a defined force acting on the respective point of the string pattern;
(d) deriving at least one local property of the string pattern at the at least three points from the at least one physical quantity and the defined force;
(e) classifying the at least three points of the string pattern using the physical quantity or quantities respectively determined there and/or using the property or properties derived for said points; and
(f) representing the string pattern by specifying the class of the at least three points of the string pattern.

2. The method according to claim 1, wherein the at least one physical quantity describing the local deformation of the string pattern comprises one or a combination of the following quantities: the vector describing the punctual three-dimensional deformation at the respective points, one or more components of said vector, the length of said vector; the punctual deflection of the string pattern at the respective points perpendicular to the string bed plane; the punctual deflection of the string pattern at the respective points parallel to the string bed plane; the vectors describing the local deformations in a defined area around the respective points, one or more components of said vectors, the length of said vectors; the local deflections of the string pattern in a defined area around the respective points perpendicular to the string bed plane; the local deflections of the string pattern in a defined area around the respective points parallel to the string bed plane.

3. The method according to claim 1, wherein the force acting on at least three points of the string pattern is a normal force.

4. The method according to claim 1, wherein the force acting on at least three points of the string pattern comprises a component parallel to the string bed plane.

5. The method according to claim 1, wherein the derived local property of the string pattern comprises one or a combination of the following properties: local stiffness, local compliance, local contact time, local stiffness in a direction perpendicular to the string bed plane, local stiffness in a direction parallel to the string bed plane, angle of deflection with respect to the string bed plane normal, local spin potential, local control properties, membrane deformation properties.

6. The method according to claim 1, wherein the classification is graphically visualized in the representation.

7. The method according to claim 1, wherein the classification is graphically visualized in the representation by assigning one or more of the following graphical parameters to predetermined classes of the classification: color value, tonal value, hatching.

8. The method according to claim 1, wherein the modeling of the string pattern is performed using the geometry of the intersecting strings and the inner contour of the racket head under one or more of the following basic conditions: definition of the inner contour of the racket head as infinitely stiff, specification of a progression of the stiffness of the racket head within and/or perpendicular to the string bed plane along the inner contour of the racket head, modeling of the string pattern as a fixed net.

9. The method according to claim 1, wherein data of the geometry of the intersecting strings and/or the inner contour of the racket head are used to model the string pattern, wherein the data of the geometry of the intersecting strings comprise the positions of the points of intersection of the strings.

10. The method according to claim 1, wherein the at least three points of the string pattern comprise at least three points of intersection.

11. The method according to claim 1, wherein the at least three points of the string pattern comprise at least five points of the string pattern.

12. The method according to claim 1, wherein the at least three points of the string pattern comprise at least ten points of the string pattern.

13. A representation of a string pattern image of a strung ball game racket frame, comprising:
a representation of the string pattern, optionally including a representation of at least a portion of the ball game racket frame; and
a classification of at least three points of the string pattern on the basis of at least one derived local property of the string pattern at said points.

14. The representation of a string pattern image according to claim 13, wherein the classification is graphically visualized in the representation, preferably by assigning one or more of the following graphical parameters to predetermined classes of the classification: color value, tonal value, hatching.

15. A set comprising a ball game racket frame and a representation of the string pattern image determined from the ball game racket frame according to claim 14.
